(19) United States
(12) Patent Application Publication
(10) Pub. No.: US 2022/0198175 A1
(43) Pub. Date: Jun. 23, 2022

(54) DISPLAY DEVICE

(71) Applicant: Au Optronics Corporation, Hsinchu (TW)

(72) Inventors: Shin-Shueh Chen, Hsinchu (TW); Chih-Chung Su, Hsinchu (TW)

(73) Assignee: Au Optronics Corporation, Hsinchu (TW)

(21) Appl. No.: 17/515,543

(22) Filed: Oct. 31, 2021

(30) Foreign Application Priority Data
Dec. 18, 2020 (TW) 109144904

(51) Int. Cl. G06K 9/00; H01L 33/62; H01L 33/42

(52) U.S. Cl. CPC G06K 9/0004; H01L 33/42; H01L 33/62

(57) ABSTRACT

A display device includes a substrate, a sensing element, a lighting-emitting element, a driving element, and a transfer wire. The substrate has a first surface, a second surface opposite to the first surface, and a side surface connecting the first surface and the second surface. The sensing element is disposed on the first surface of the substrate, and the lighting-emitting element is disposed on the second surface of the substrate. The driving element is disposed on the first surface or the second surface of the substrate. The transfer wire is disposed on the side surface of the substrate. The driving element is electrically connected to the lighting-emitting element or the sensing element via the transfer wire. An orthogonal projection of the sensing element on the substrate is located outside an orthogonal projection of the lighting-emitting element on the substrate.

### CROSS-REFERENCE TO RELATED APPLICATION

This application claims the priority benefit of Taiwan patent application no. 109144904, filed on Dec. 18, 2020. The entirety of the above-mentioned patent application is hereby incorporated by reference herein and made a part of this specification.

### BACKGROUND

### Technical Field

The disclosure relates to a display device; more particularly, the disclosure relates to a display device including a sensing element.

### Description of Related Art

In order to improve convenience of using products, many manufacturers install sensing elements in the products. For instance, the existing display devices are often equipped with the sensing elements capable of performing fingerprint recognition functions. According to the existing fingerprint recognition technology, the sensing element detects a light beam reflected by fingerprints. The ridges and furrows of the fingerprint may lead to different intensities of the reflected light beam. Therefore, different light intensities may cause the sensing element to generate different magnitudes of current, whereby the fingerprint patterns may be distinguished.

In order to increase a screen-to-body ratio of the display device, the sensing element of the existing display device is disposed in a display region. However, the arrangement of the sensing element in the display region may pose a negative impact on an aperture ratio of the display device, i.e., reduce the aperture ratio of the display device.

### SUMMARY

The disclosure provides a display device whose sensing element does not affect an aperture ratio of the display device.

According to an embodiment of the disclosure, a display device is provided. The display device includes a substrate, a sensing element, a light-emitting element, a driving element, and a transfer wire. The substrate has a first surface, a second surface, and a side surface, the first surface and the second surface are opposite to each other, and the side surface is connected to the first surface and the second surface. The sensing element is disposed on the first surface of the substrate, and the light-emitting element is disposed on the second surface of the substrate. The driving element is disposed on the first surface or the second surface of the substrate. The transfer wire is disposed on the side surface of the substrate. Here, the driving element is electrically connected to the light-emitting element or the sensing element via the transfer wire, and an orthogonal projection of the sensing element on the substrate is located outside an orthogonal projection of the light-emitting element on the substrate.

According to another embodiment of the disclosure, a display device is provided. The display device includes a substrate, a sensing element, a light-emitting element, and a cover plate. The substrate has a first surface and a second surface, and the first surface and the second surface are opposite to each other. The sensing element is disposed on the first surface of the substrate, and the light-emitting element is disposed on the second surface of the substrate. The cover plate is disposed on one side of the sensing element. Here, the sensing element is located between the cover plate and the substrate, and an orthogonal projection of the sensing element on the substrate is located outside an orthogonal projection of the light-emitting element on the substrate.

To make the above more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic cross-sectional view of a display device according to an embodiment of the disclosure.

FIG. 2 is a schematic enlarged view of a region I in the display device depicted in FIG. 1.

FIG. 3 is a schematic enlarged view of a region II in the display device depicted in FIG. 1.

FIG. 4 is a schematic cross-sectional view of a display device according to an embodiment of the disclosure.

FIG. 5 is a schematic enlarged view of a region III in the display device depicted in FIG. 4.

FIG. 6 is a schematic enlarged view of a region IV in the display device depicted in FIG. 4.

FIG. 7 is a schematic cross-sectional view of a portion of a display device according to an embodiment of the disclosure.

FIG. 8 is a schematic cross-sectional view of a portion of a display device according to an embodiment of the disclosure.

FIG. 9 is a schematic cross-sectional view of a portion of a display device according to an embodiment of the disclosure.

FIG. 10 is a schematic cross-sectional view of a portion of a display device according to an embodiment of the disclosure.

FIG. 11 is a schematic cross-sectional view of a portion of a display device according to an embodiment of the disclosure.

FIG. 12 is a schematic cross-sectional view of a portion of a display device according to an embodiment of the disclosure.

### DESCRIPTION OF THE EMBODIMENTS

In the accompanying drawings, thicknesses of layers, films, panels, regions, and the like are exaggerated for clarity. Throughout the specification, the same reference numerals denote the same elements. It should be understood that when an element, such as a layer, a film, a region, or a substrate, is referred to as being “on” or “connected to” another element, it can be directly on or connected to such another element, or intervening elements may also be present. By contrast, when an element is referred to as being “directly on” or “directly connected to” another element, there is no intervening element present. As used herein, the term “connected” may refer to “physically connected” and/or “electrically connected”. Therefore, “electrical connection” or “coupling” between two elements may be understood as intervening elements existing between the two elements.

Moreover, relative terms such as “under” or “bottom” and “above” or “top” may be used for describing a relationship of one element and another element as that shown in figures. It should be understood that the relative terms are intended to include a different orientation of the element besides the orientation shown in the figure. For example, if an element in a figure is flipped over, the element originally described to be located “under” another element is oriented to be located “above” such another element. Therefore, the illustrative term “under” may include orientations of “under” and “on”, which is determined by the specific orientation of the figure. Similarly, if an element in a figure is flipped over, the element originally described to be located “below” or “underneath” another element is oriented to be located “on” such another element. Therefore, the illustrative term “under” or “below” may include orientations of “above” and “under”.

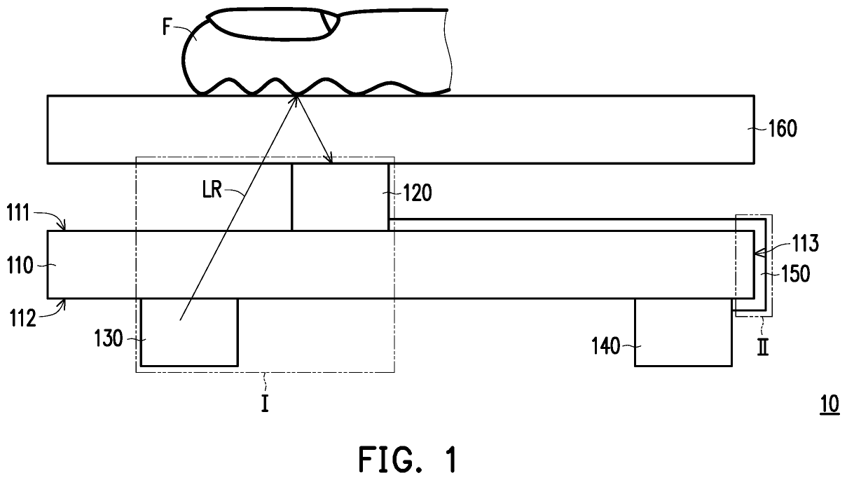

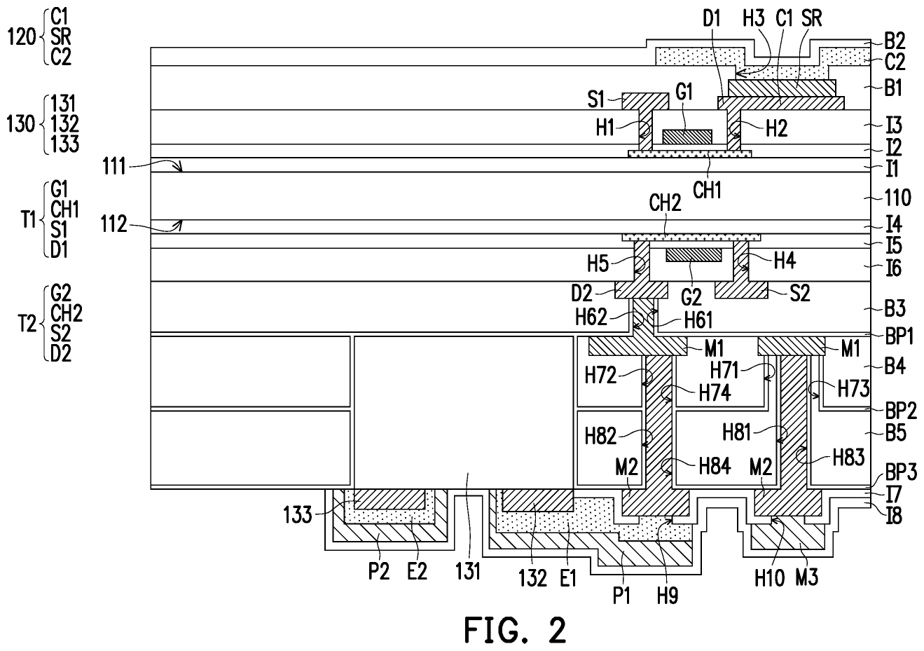

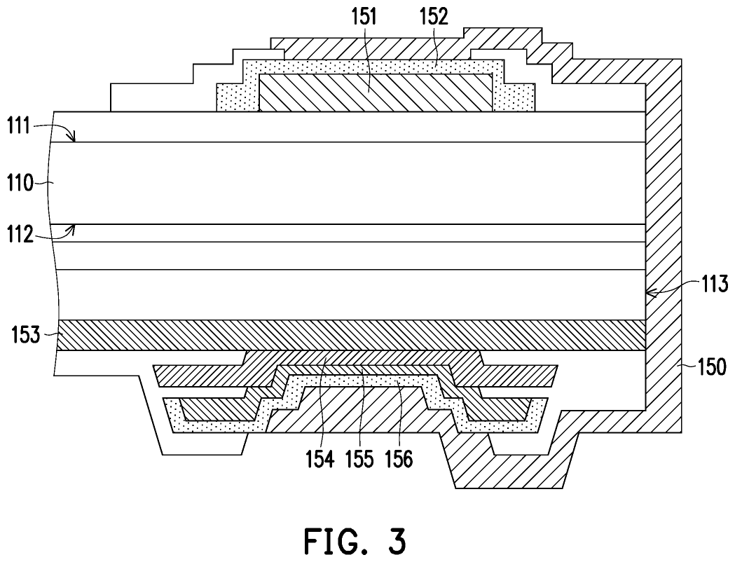

FIG. 1 is a schematic cross-sectional view of a display device 10 according to an embodiment of the disclosure. FIG. 2 is a schematic enlarged view of a region I in the display device 10 depicted in FIG. 1. FIG. 3 is a schematic enlarged view of a region II in the display device 10 depicted in FIG. 1. To simplify the illustrations, detailed components in a sensing element 120, a light-emitting element 130, and a transfer wire 150 in FIG. 2 and FIG. 3 are omitted in FIG. 1. The entire structure of a display panel may be clearly comprehended with reference to FIG. 1 to FIG. 3.

As shown in FIG. 1, the display device 10 includes: a substrate 110, the sensing element 120, the light-emitting element 130, a driving element 140, and the transfer wire 150. The substrate 110 has a first surface 111, a second surface 112, and a side surface 113, the first surface 111 and the second surface 112 are opposite to each other, and the side surface 113 is connected to the first surface 111 and the second surface 112. The sensing element 120 is disposed on the first surface 111 of the substrate 110. The light-emitting element 130 is disposed on the second surface 112 of the substrate 110. The driving element 140 is disposed on the second surface 112 of the substrate 110. The transfer wire 150 is disposed on the side surface 113 of the substrate 110. Here, the driving element 140 is electrically connected to the sensing element 120 via the transfer wire 150, and an orthogonal projection of the sensing element 120 on the substrate 110 is located outside an orthogonal projection of the light-emitting element 130 on the substrate 110.

In view of the above, in the display device 10 provided in an embodiment of the disclosure, the sensing element 120 and the light-emitting element 130 are disposed on different surfaces of the substrate 110, and therefore the sensing element 120 does not cause an aperture ratio of the display device 10 to decrease.

The implementation manner of each element and film layer in the display device 10 is further explained below with reference to FIG. 2 and FIG. 3, which should however not be construed as limitations in the disclosure.

In this embodiment, the substrate 110 is a transparent substrate, and a material of the substrate 110 is, for instance, quartz, glass, polymer, or other appropriate materials, which should however not be construed as a limitation in the disclosure. Various film layers for forming the sensing element 120, the light-emitting element 130, the driving element 140, the transfer wire 150, and other elements, such as signal lines, switch elements, and storage capacitors, may be arranged on the substrate 110.

With reference to FIG. 2, on the first surface 111 of the substrate 110, the display device 10 may include a first switch element T1, and the first switch element T1 is electrically connected to the sensing element 120. An orthogonal projection of the first switch element T1 on the substrate 110 is located outside the orthogonal projection on the light-emitting element 130 on the substrate 110 to prevent light emitted by the light-emitting element 130 from being blocked.

The first switch element T1 is located on an insulating layer I1, for instance. The first switch element T1 includes a gate G1, a source S1, a drain D1, and a semiconductor layer CH1. The semiconductor layer CH1 is located on the insulating layer I1. The gate G1 overlaps with the semiconductor layer CH1, and an insulating layer I2 is sandwiched between the gate G1 and the semiconductor layer CH1. An insulating layer I3 is located on the insulating layer I2. The source S1 and the drain D1 are located above the insulating layer I3, and the source S1 and the drain D1 are electrically connected to the semiconductor layer CH1 respectively via through holes H1 and H2. The through holes H1 and H2 are located in the insulating layer I3 and the insulating layer I2, for instance. The gate G1 may be electrically connected to the driving element 140 via a scan line (not shown) and the transfer wire 150, and the source S1 may be electrically connected to the driving element 140 via a data line (not shown) and the transfer wire 150. In this embodiment, a material of the semiconductor layer CH1 may include a silicon semiconductor material, such as polysilicon, which should however not be construed as a limitation in the disclosure. The first switch element T1 is implemented in form of a top-gate thin film transistor (TFT) as an example, which should however not be construed as a limitation in the disclosure. According to other embodiments, the first switch element T1 may also be a bottom-gate TFT or any other suitable TFT.

The insulating layer B1 covers the first switch element T1. The sensing element 120 is electrically connected to the first switch element T1. The sensing element 120 includes an opposite electrode C1, a transparent electrode C2, and a sensing layer SR.

The opposite electrode C1 is located on the insulating layer I3, and the opposite electrode C1 is electrically connected to the first switch element T1. For instance, the opposite electrode C1 is electrically connected to the drain D1. In this embodiment, the opposite electrode C1, the source S1, and the drain D1 belong to the same film layer. In some embodiments, the opposite electrode C1 and the drain D1 are physically connected to each other. In this embodiment, the opposite electrode C1 is closer to the substrate 110 than the transparent electrode C2. A material of the opposite electrode C1 is, for instance, molybdenum, aluminum, titanium, copper, gold, silver, other conductive materials, or two or more of the foregoing materials stacked together.

The sensing layer SR is disposed on the opposite electrode C1. A material of the sensing layer SR is, for instance, silicon-rich oxide (SRO) or other suitable materials. In this embodiment, the opposite electrode C1 is located between the sensing layer SR and the substrate 110.

The transparent electrode C2 is disposed in a groove H3 of the insulating layer B1 and is located on the sensing layer SR, so that the sensing layer SR is sandwiched between the opposite electrode C1 and the transparent electrode C2, and that the sensing layer SR is located between the transparent electrode C2 and the substrate 110. A material of the transparent electrode C2 is a transparent conductive material, such as indium tin oxide (ITO), indium zinc oxide (IZO), aluminum tin oxide (ATO), aluminum zinc oxide (AZO), indium gallium zinc oxide (IGZO), other suitable oxides, or a stacked layer containing at least two of the above-mentioned materials. In this embodiment, the display device 10 may further include a passivation layer B2, and the passivation layer B2 may cover the transparent electrode C2.

On the second surface 112 of the substrate 110, the display device 10 may include a second switch element T2, and the second switch element T2 is electrically connected to the light-emitting element 130. An orthogonal projection of the second switch element T2 on the substrate 110 is located outside the orthogonal projection on the light-emitting element 130 on the substrate 110 to prevent the light emitted by the light-emitting element 130 from being blocked. In some embodiments, the orthogonal projection of the second switch element T2 on the substrate 110 overlaps with the orthogonal projection of the first switch element T1 on the substrate 110, which is conducive to an increase in the aperture ratio of the display device 10.

The second switch element T2 is located on an insulating layer I4, for instance. The second switch element T2 includes a gate G2, a source S2, a drain D2, and a semiconductor layer CH2. The semiconductor layer CH2 is located on the insulating layer I4. The gate G2 overlaps with the semiconductor layer CH2, and an insulating layer I5 is sandwiched between the gate G2 and the semiconductor layer CH2. An insulating layer I6 is located on the insulating layer I5. The source S2 and the drain D2 are located above the insulating layer I6, and the source S2 and the drain D2 are electrically connected to the semiconductor layer CH2 respectively via through holes H4 and H5. The through holes H4 and H5 are located in the insulating layer I6 and the insulating layer I5, for instance. The gate G2 may be electrically connected to the driving element 140 via a scan line (not shown), and the source S2 may be electrically connected to the driving element 140 via a data line (not shown). In this embodiment, a material of the semiconductor layer CH2 may include a silicon semiconductor material (e.g., polysilicon, amorphous silicon, etc.), an oxide semiconductor material, and an organic semiconductor material, which should however not be construed as a limitation in the disclosure. The second switch element T2 is implemented in form of a top-gate TFT as an example, which should however not be construed as a limitation in the disclosure. According to other embodiments, the second switch element T2 may also be a bottom-gate TFT or any other suitable TFT.

The display device 10 further includes an insulating layer B3, an insulating layer BP1, a conductive wire layer M1, an insulating layer B4, an insulating layer BP2, an insulating layer B5, an insulating layer BP3, a conductive wire layer M2, and an insulating layer I7. The insulating layer B3 covers the second switch element T2 and is sandwiched between the insulating layer BP1 and the source S2 and the drain D2. The insulating layer B3 has a through hole H61. The insulating layer BP1 covers the insulating layer B3, and the insulating layer BP1 has a through hole H62. The through hole H62 overlaps with the through hole H61, and the through hole H62 exposes the drain D2. The conductive wire layer M1 is disposed on the insulating layer BP1, and the conductive wire layer M1 is connected to the drain D2 via the through hole H62 in the insulating layer BP1. The insulating layer B4 is sandwiched between the insulating layer BP2 and the conductive wire layer M1 and the insulating layer BP1, and the insulating layer B4 has a through hole H71 and a through hole H72. The insulating layer BP2 has a through hole H73 and a through hole H74. The through hole H73 overlaps with the through hole H71 and exposes the conductive wire layer M1, and the through hole H74 overlaps with the through hole H72 and exposes the conductive wire layer M1. The insulating layer B5 is sandwiched between the insulating layer BP3 and the insulating layer BP2, and the through hole H73 is filled with the insulating layer B5. The insulating layer B5 has a through hole H81 and a through hole H82. The insulating layer BP3 is sandwiched between the insulating layer B5 and the conductive wire layer M2, and the insulating layer BP3 has a through hole H83 and a through hole H84. The through hole H83 overlaps with the through hole H81 and the through hole H73 to expose the conductive wire layer M1, and the through hole H84 overlaps with the through hole H82 and the through hole H74 to expose the conductive wire layer M1. The insulating layer BP1, the insulating layer BP2, and the insulating layer BP3 may enhance adhesion among the insulating layer B3, the insulating layer B4, the insulating layer B5, and the insulating layer I7. The conductive wire layer M2 is connected to the conductive wire layer M1 via the through holes H83 and H84 in the insulating layer BP3.

In this embodiment, the light-emitting element 130 is disposed in the insulating layer B4, the insulating layer BP2, the insulating layer B5, and the insulating layer BP3, which should however not be construed as a limitation in the disclosure. For instance, in some embodiments, the light-emitting element 130 may also be disposed in the insulating layer B3, the insulating layer BP1, the insulating layer B4, the insulating layer BP2, the insulating layer B5, and the insulating layer BP3.

The light-emitting element 130 may include a light-emitting body 131, a first electrode 132, and a second electrode 133. In this embodiment, the first electrode 132 and the second electrode 133 of the light-emitting element 130 are arranged on the same side of the light-emitting body 131. For instance, the light-emitting element 130 provided in this embodiment is a horizontal micro light-emitting diode (micro-LED), the first electrode 132 is an anode, and the second electrode 133 is a cathode, which should however not be construed as a limitation in the disclosure.

In this embodiment, the first electrode 132 is electrically coupled to a first pad P1, and the first electrode 132 of each light-emitting element 130 is electrically connected to one first pad P1, respectively. In this embodiment, the second electrode 133 is electrically coupled to a second pad P2, and the second electrodes 133 of a plurality of light-emitting elements 130 are electrically connected to one second pad P2. In other embodiments, the first electrode 132 is electrically coupled to the second pad P2, and the second electrode 133 is electrically coupled to the first pad P1. In this embodiment, a material of the first electrode 132 and the second electrode 133 may include alloy, metal nitride, metal oxide, metal oxynitride, other suitable materials, a stacked layer containing metal materials and other conductive materials, or other materials with low resistance.

For instance, the light-emitting element 130 is formed on a growth substrate, transferred to the substrate 110 through a mass transfer process, and electrically connected to the first pad P1 and the second pad P2 via a first connection layer E1 and a second connection layer E2. The first connection layer E1 may also be connected to the conductive wire layer M2 via the through hole H9 of the insulating layer I7, so that the first electrode 132 may be electrically connected to the drain D2 of the second switch element T2. The display device 10 may further include a conductive wire layer M3, and the conductive wire layer M3 may be electrically connected to the conductive wire layer M2 via a through hole H10 of the insulating layer I7. In addition, the second pad P2 may also be connected to the driving element 140 via other conductive wires. The first connection layer E1 and the second connection layer E2 are, for instance, a solder material, a conductive adhesive, or conductive oxide. In this embodiment, the display device 10 may further include an insulating layer I8, and the insulating layer I8 may cover the first pad P1, the second pad P2, and the conductive wire layer M3.

As shown in FIG. 1, the display device 10 further includes a cover plate 160. The cover plate 160 is disposed on one side of the sensing element 120, and the sensing element 120 is located between the cover plate 160 and the substrate 110. For instance, the passivation layer B2 shown in FIG. 2 may be located between the transparent electrode C2 of the sensing element 120 and the cover plate 160.

When a finger F approaches the cover plate 160, a light beam LR emitted by the light-emitting element 130 may be reflected by the finger F to the sensing element 120. In this embodiment, since the sensing element 120 and the cover plate 160 are located on the same side of the substrate 110, fingerprints on the finger F may be closer to the sensing element 120, so that most of a reflected light beam generated by reflecting the light beam LR by the finger F may be received by the sensing element 120, and that the sensing element 120 may sense relatively clear finger ridge/furrow signals.

With reference to FIG. 1 and FIG. 3, in this embodiment, the transfer wire 150 is disposed on the side surface 113 of the substrate 110 and is electrically connected to the sensing element 120 on the first surface 111 and the driving element 140 on the second surface 112.

Specifically, in this embodiment, the sensing element 120 is electrically connected to the conductive wire layer I51 located on the first surface 111 of the substrate 110, and the conductive wire layer I51 is then connected to the conductive wire layer I52. The driving element 140 is electrically connected to a signal line 153 on the second surface 112 of the substrate 110, the signal line 153 is connected to the conductive wire layer I54, the conductive wire layer I54 is connected to the conductive wire layer I55, and the conductive wire layer I55 is connected to the conductive wire layer I56. Two ends of the transfer wire 150 respectively extend from the side surface 113 of the substrate 110 to the first surface 111 and the second surface 112 of the substrate 110, and the two ends of the transfer wire 150 are electrically connected to the conductive wire layer I51 on the first surface 111 and the signal line 153 on the second surface 112, respectively. Here, the two ends of the transfer wire 150 contact the conductive wire layer I52 and the conductive wire layer I56, respectively. As such, the sensing element 120 located on the first surface 111 of the substrate 110 may be electrically connected to the driving element 140 located on the second surface 112 of the substrate 110. In this embodiment, a material of the transfer wire 150 may be metal or alloy, such as gold, silver, copper, aluminum, titanium, molybdenum, or a combination thereof, and so on, which should however not be construed as a limitation in the disclosure.

According to this embodiment, the transfer wire 150 is electrically connected to the sensing element 120 on the first surface 111 and the driving element 140 on the second surface 112, which allows the display device to have a slim border and improves a screen-to-body ratio.

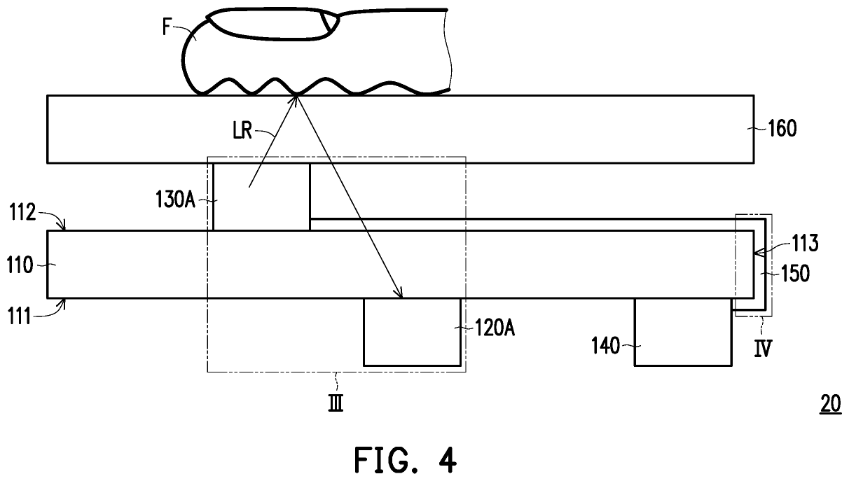

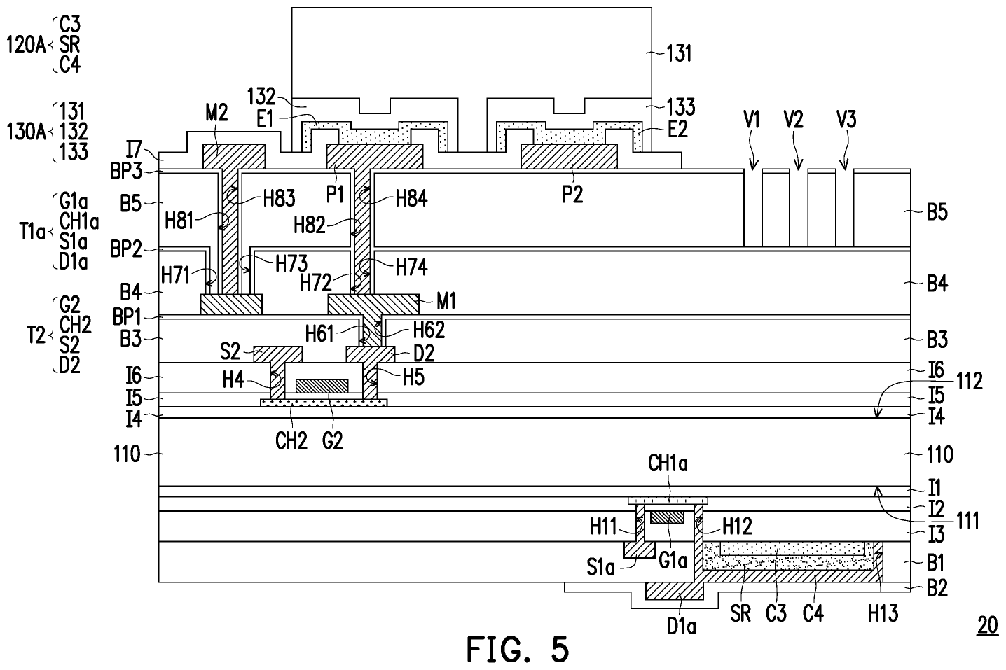

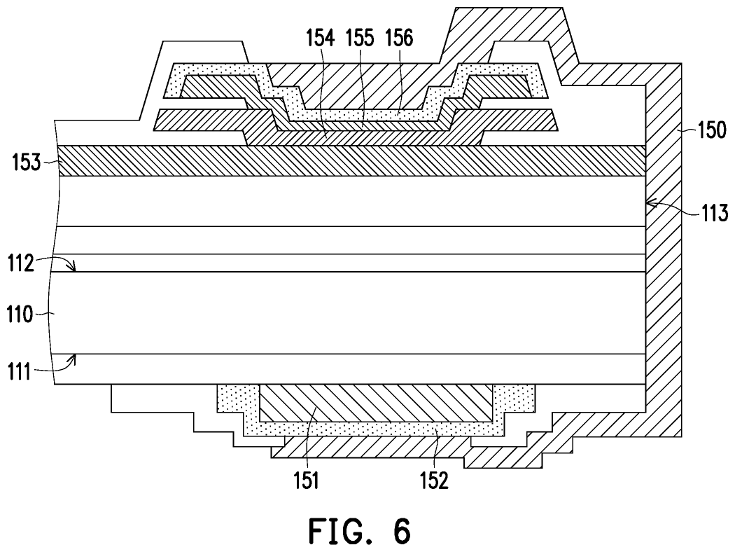

Another embodiment of the disclosure is further explained hereinafter. FIG. 4 is a schematic cross-sectional view of a display device 20 according to an embodiment of the disclosure. FIG. 5 is a schematic enlarged view of a region III in the display device 20 depicted in FIG. 4. FIG. 6 is a schematic enlarged view of a region II in the display device 20 depicted in FIG. 4. To simplify the illustrations, detailed components in a sensing element 120A, a light-emitting element 130A, and the transfer wire 150 in FIG. 5 and FIG. 6 are omitted in FIG. 4. The implementation manner of each element and film layer is further explained below with reference to FIG. 4 to FIG. 6, and the reference numbers and relevant contents illustrated in FIG. 1 to FIG. 3 are also applicable in the following embodiment, which should however not be construed as limitations in the disclosure.

As shown in FIG. 4, the display device 20 includes: the substrate 110, a sensing element 120A, a light-emitting element 130A, the driving element 140, and the transfer wire 150. The substrate 110 has the first surface 111, the second surface 112, and the side surface 113, the first surface 111 and the second surface 112 are opposite to each other, and the side surface 113 is connected to the first surface 111 and the second surface 112. The sensing element 120A is disposed on the first surface 111 of the substrate 110. The light-emitting element 130A is disposed on the second surface 112 of the substrate 110. The driving element 140 is disposed on the first surface 111 of the substrate 110. The transfer wire 150 is disposed on the side surface 113 of the substrate 110. Here, the driving element 140 is electrically connected to the light-emitting element 130A via the transfer wire 150, and an orthogonal projection of the sensing element 120A on the substrate 110 is located outside the orthogonal projection of the light-emitting element 130A on the substrate 110.

In view of the above, in the display device 20 provided in an embodiment of the disclosure, the sensing element 120A and the light-emitting element 130A are disposed on different surfaces of the substrate 110, and therefore the sensing element 120A does not affect the aperture ratio of the display device 20.

With reference to FIG. 5, on the first surface 111 of the substrate 110, the display device 20 may include a first switch element T1a, and the first switch element T1a is electrically connected to the sensing element 120A. In this embodiment, an orthogonal projection of the first switch element T1a on the substrate 110 may overlap with the orthogonal projection of the light-emitting element 130A on the substrate 110.

The first switch element T1a is located on the insulating layer I1, for instance. The first switch element T1a includes a gate G1a, a source S1a, a drain D1a, and a semiconductor layer CH1a. The semiconductor layer CH1a is located on the insulating layer I1. The gate G1a overlaps with the semiconductor layer CH1a, and the insulating layer I2 is sandwiched between the gate G1a and the semiconductor layer CH1a. The insulating layer I3 is located on the insulating layer I2, and the insulating layer B1 is located on the insulating layer I3. The source S1a is located above the insulating layer I3, the drain D1a is located above the insulating layer B1, and the source S1a and the drain D1a are electrically connected to the semiconductor layer CH1a via through holes H11 and H12, respectively. The through hole H11 is located in the insulating layer I2 and the insulating layer I3, for instance, and the through hole H12 is located in the insulating layer I2, the insulating layer I3, and the insulating layer B1, for instance. The gate G1a may be electrically connected to the driving element 140 via a scan line (not shown), and the source S1 may be electrically connected to the driving element 140 via a data line (not shown). In this embodiment, a material of the semiconductor layer CH1a may include silicon semiconductor material, such as polysilicon, amorphous silicon, and so on, which should however not be construed as a limitation in the disclosure. The first switch element T1a is implemented in form of a top-gate TFT as an example, which should however not be construed as a limitation in the disclosure. According to other embodiments, the first switch element T1a may also be a bottom-gate TFT or another suitable TFT.

The sensing element 120A is disposed in a groove H13 of the insulating layer B1 and is electrically connected to the drain D1a of the first switch element T1a. The sensing element 120A includes a transparent electrode C3, an opposite electrode C4, and the sensing layer SR.

The transparent electrode C3 is disposed on one side of the insulating layer I3. A material of the transparent electrode C3 is a transparent conductive material, such as ITO, IZO, ATO, AZO, IGZO, other suitable oxides, or a stacked layer containing at least two of the above-mentioned materials.

The sensing layer SR is located on one side of the transparent electrode C3; that is, the transparent electrode C3 is disposed on one side of the sensing layer SR, and the transparent electrode C3 is located between the sensing layer SR and the substrate 110. A material of the sensing layer SR is, for instance, SRO or other suitable materials.

The opposite electrode C4 is disposed on the other side of the sensing layer SR; that is, the sensing layer SR is located between the opposite electrode C4 and the transparent electrode C3, and the sensing layer SR is disposed on one side of the opposite electrode C4. In this embodiment, an orthogonal projection of the transparent electrode C3 on the substrate 110 overlaps with an orthogonal projection of the opposite electrode C4 on the substrate 110.

The opposite electrode C4 is electrically connected to the first switch element T1a. For instance, the opposite electrode C4 is electrically connected to the drain D1a. In some embodiments, the opposite electrode C4 and the drain D1a are physically connected to each other. In some embodiments, the transparent electrode C3 is closer to the substrate 110 than the opposite electrode C4. A material of the opposite electrode C4 is, for instance, molybdenum, aluminum, titanium, copper, gold, silver, other conductive materials, or two or more of the above-mentioned materials stacked together. In this embodiment, the display device 20 may further include the passivation layer B2, and the passivation layer B2 may cover the first switch element T1a and the opposite electrode C4.

On the second surface 112 of the substrate 110, the display device 20 may include the same second switch element T2 as the second switch element T2 in the display device 10 provided in the previous embodiment, and the second switch element T2 is electrically connected to the light-emitting element 130A. In some embodiments, the orthogonal projection of the second switch element T2 on the substrate 110 may overlap with the orthogonal projection of the light-emitting element 130A on the substrate 110, or the orthogonal projection of the first switch element T1a on the substrate 110 may overlap with the orthogonal projection of the light-emitting element 130A or the second switch element T2 on the substrate 110, which is conducive to an increase in the aperture ratio of the display device 20.

The second switch element T2 includes the gate G2, the source S2, the drain D2, and the semiconductor layer CH2. The gate G2 overlaps with the semiconductor layer CH2, and the insulating layer I5 is sandwiched between the gate G2 and the semiconductor layer CH2. The insulating layer I6 is located on the insulating layer I5. The source S2 and the drain D2 are located above the insulating layer I6, the source S2 and the drain D2 are electrically connected to the semiconductor layer CH2 via the through holes H4 and H5, and the through holes H4 and H5 are located in the insulating layer I6 and the insulating layer I5, for instance. The gate G2 may be electrically connected to the driving element 140 via a scan line (not shown) and the transfer wire 150, and the source S2 may be electrically connected to the driving element 140 via a data line (not shown) and the transfer wire 150.

In this embodiment, a material of the semiconductor layer CH2 may include silicon semiconductor material (e.g., polysilicon, amorphous silicon, etc.), an oxide semiconductor material, and an organic semiconductor material, which should however not be construed as a limitation in the disclosure.

The display device 20 further includes the insulating layer B3, the insulating layer BP1, the conductive wire layer M1, the insulating layer B4, the insulating layer BP2, the insulating layer B5, the insulating layer BP3, the conductive wire layer M2, and the insulating layer I7. The insulating layer B3 covers the second switch element T2 and is sandwiched between the insulating layer BP1 and the source S2 and the drain D2. The insulating layer B3 has the through hole H61. The insulating layer BP1 covers the insulating layer B3, and the insulating layer BP1 has the through hole H62. The through hole H62 overlaps with the through hole H61, and the through hole H62 exposes the drain D2. The conductive wire layer M1 is disposed on the insulating layer BP1, and the conductive wire layer M1 is connected to the drain D2 via the through hole H62 in the insulating layer BP1. The insulating layer B4 is sandwiched between the insulating layer BP2 and the conductive wire layer M1 and the insulating layer BP1, and the insulating layer B4 has the through hole H71 and the through hole H72. The insulating layer BP2 has the through hole H73 and the through hole H74. The through hole H73 overlaps with the through hole H71 and exposes the conductive wire layer M1, and the through hole H74 overlaps with the through hole H72 and exposes the conductive wire layer M1. The insulating layer B5 is sandwiched between the insulating layer BP3 and the insulating layer BP2, and the through hole H73 is filled with the insulating layer B5. The insulating layer B5 has the through hole H81 and the through hole H82. The insulating layer BP3 is sandwiched between the insulating layer B5 and the conductive wire layer M2, and the insulating layer BP3 has the through hole H83 and the through hole H84. The through hole H83 overlaps with the through hole H81 and the through hole H73 and exposes the conductive wire layer M1, and the through hole H84 overlaps with the through hole H82 and the through hole H74 and exposes the conductive wire layer M1. The insulating layer BP1, the insulating layer BP2, and the insulating layer BP3 may enhance adhesion among the insulating layer B3, the insulating layer B4, the insulating layer B5, and the insulating layer I7. The conductive wire layer M2 is connected to the conductive wire layer M1 via the through holes H83 and H84 in the insulating layer BP3.

In this embodiment, the light-emitting element 130A is disposed above the insulating layer I7, which should however not be construed as a limitation in the disclosure. The light-emitting element 130A may include the light-emitting body 131, the first electrode 132, and the second electrode 133. In this embodiment, the first electrode 132 and the second electrode 133 of the light-emitting element 130A are arranged on the same side of the light-emitting body 131. For instance, the light-emitting element 130A provided in this embodiment is a horizontal micro-LED, the first electrode 132 is an anode, and the second electrode 133 is a cathode, which should however 150. not be construed as a limitation in the disclosure.

In this embodiment, the first electrode 132 is electrically coupled to the first pad P1, and the first electrode 132 of each light-emitting element 130A is electrically connected to one first pad P1, respectively. In this embodiment, the second electrode 133 is electrically coupled to the second pad P2, and the second electrodes 133 of a plurality of light-emitting elements 130 are electrically connected to one second pad P2. In other embodiments, the first electrode 132 is electrically coupled to the second pad P2, and the second electrode 133 is electrically coupled to the first pad P1. In this embodiment, a material of the first electrode 132 and the second electrode 133 may include alloy, metal nitride, metal oxide, metal oxynitride, other suitable materials, or a stacked layer containing metal materials and other conductive materials, or other materials with low resistance.

For instance, the light-emitting element 130A is formed on a growth substrate, transferred to the substrate 110 through a mass transfer process, and electrically connected to the first pad P1 and the second pad P2 via the first connection layer E1 and the second connection layer E2, respectively. The second pad P2 may also be connected to the driving element 140 via other conductive wires and the transfer wire 150. The first connection layer E1 and the second connection layer E2 are, for instance, a solder material, a conductive adhesive, or conductive oxide.

The display device 20 may include at least one through hole, and an orthogonal projection of the at least one through hole on the substrate 110 overlaps with the orthogonal projection of the sensing element 120A on the substrate 110. For instance, in this embodiment, the display device 20 includes a through hole V1, a through hole V2, and a through hole V3, wherein the through hole V1, the through hole V2, and the through hole V3 penetrate the insulating layer BP3 and the insulating layer B5. In the disclosure, the number of through holes is not particularly limited and may be determined according to actual needs. In addition, the through hole V1, the through hole V2, and the through hole V3 may be formed by etching, mechanical drilling, laser ablation, or other precision processing methods, which should however not be construed as a limitation in the disclosure.

With reference to FIG. 4 and FIG. 5, the display device 20 may further include the cover plate 160. The cover plate 160 is disposed on one side of the light-emitting element 130A, so that the light-emitting element 130A is located between the cover plate 160 and the substrate 110, and that the substrate 110 is located between the cover plate 160 and the sensing element 120A. When the finger F approaches the cover plate 160, the light beam LR emitted by the light-emitting element 130A may be reflected by the finger F to the sensing element 120A. In this embodiment, since the through hole V1, the through hole V2, and the through hole V3 achieve light collimation effects, a reflected light beam generated by reflecting the light beam LR by the finger F may be received by the sensing element 120 in a more collimated manner, so that the sensing element 120A may sense relatively clear finger ridge/furrow signals.

With reference to FIG. 6, in this embodiment, the transfer wire 150 is disposed on the side surface 113 of the substrate 110 and electrically connected to the driving element 140 on the first surface 111 and the light-emitting element 130A on the second surface 112.

Specifically, in this embodiment, the driving element 140 is electrically connected to the conductive wire layer I51 located on the first surface 111 of the substrate 110, and the conductive wire layer I51 is then connected to the conductive wire layer I52. The light-emitting element 130A is electrically connected to the signal line 153 located on the second surface 112 of the substrate 110, the signal line 153 is connected to the conductive wire layer I54, the conductive wire layer I54 is connected to the conductive wire layer I55, and the conductive wire layer I55 is then connected to the conductive wire layer I56. The transfer wire 150 is disposed on the side surface 113 of the substrate 110, and two ends of the transfer wire 150 are electrically connected to the conductive wire layer I51 on the first surface 111 and the signal line 153 on the second surface 112, respectively. Here, the two ends of the transfer wire 150 contact the conductive wire layer I52 and the conductive wire layer I56, respectively. Thereby, the light-emitting element 130A located on the second surface 112 of the substrate 110 may be electrically connected to the driving element 140 located on the first surface 111 of the substrate 110.

In this embodiment, the transfer wire 150 is electrically connected to the driving element 140 on the first surface 111 and the light-emitting element 130A on the second surface 112, whereby the screen-to-body ratio of the display device may be improved.

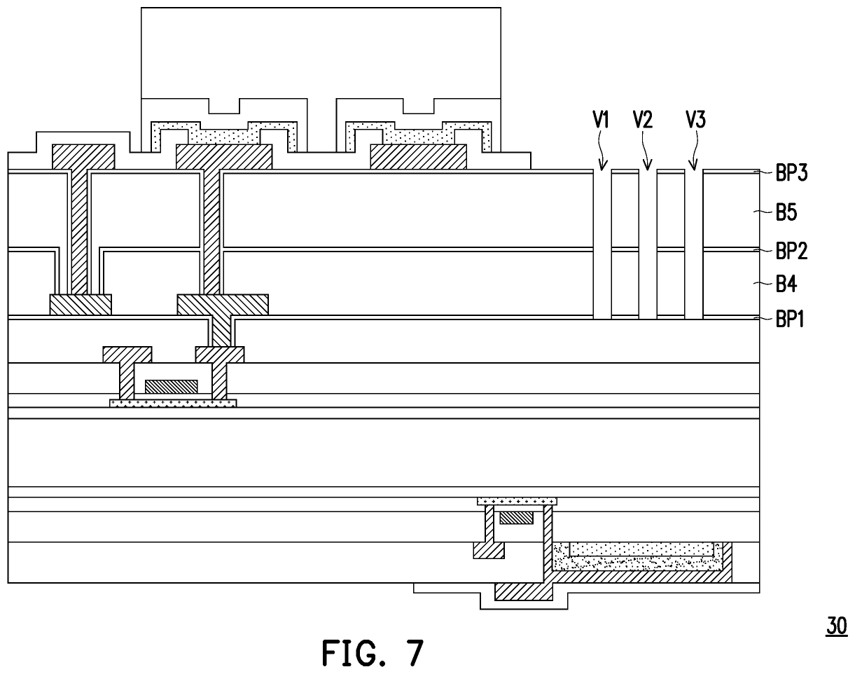

Other embodiments are further explained below with reference to FIG. 7 to FIG. 9, and the reference numbers and relevant contents illustrated in FIG. 4 to FIG. 6 are also applicable in the following embodiments, which should however not be construed as limitations in the disclosure.

FIG. 7 is a schematic cross-sectional view of a portion of a display device 30 according to an embodiment of the disclosure. Compared with the display device 20 shown in FIG. 5, the display device 30 shown in FIG. 7 is different in that: the through hole V1, the through hole V2, and the through hole V3 penetrate the insulating layer BP3, the insulating layer B5, the insulating layer BP2, the insulating layer B4, and the insulating layer BP1. Thereby, the display device 30 may achieve an improved light collimation effect.

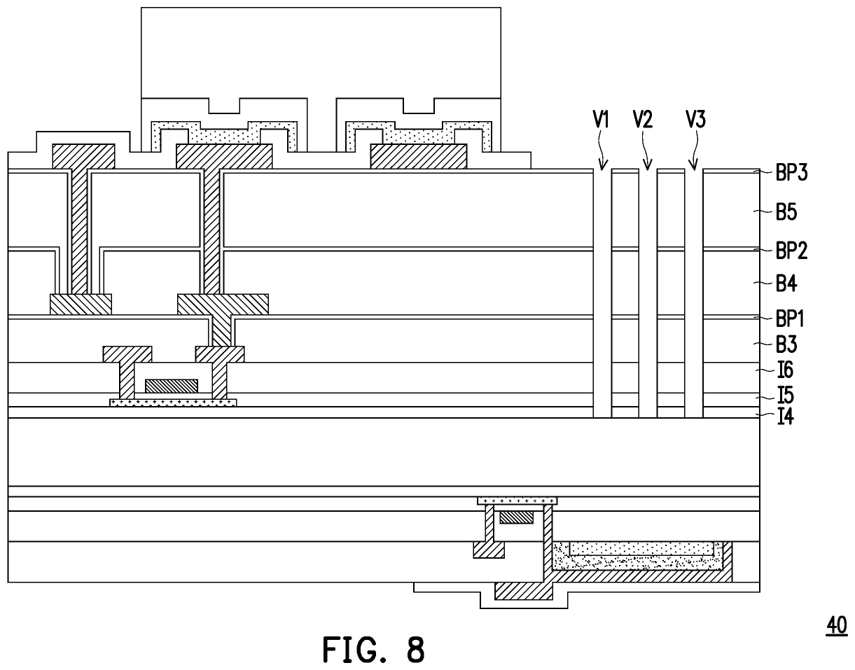

FIG. 8 is a schematic cross-sectional view of a portion of a display device 40 according to an embodiment of the disclosure. Compared with the display device 20 shown in FIG. 5, the display device 40 shown in FIG. 8 is different in that: the through hole V1, the through hole V2, and the through hole V3 penetrate the insulating layer BP3, the insulating layer B5, the insulating layer BP2, the insulating layer B4, the insulating layer BP1, the insulating layer B3, the insulating layer I6, the insulating layer I5, and the insulating layer I4. Thereby, the display device 40 may achieve an improved light collimation effect.

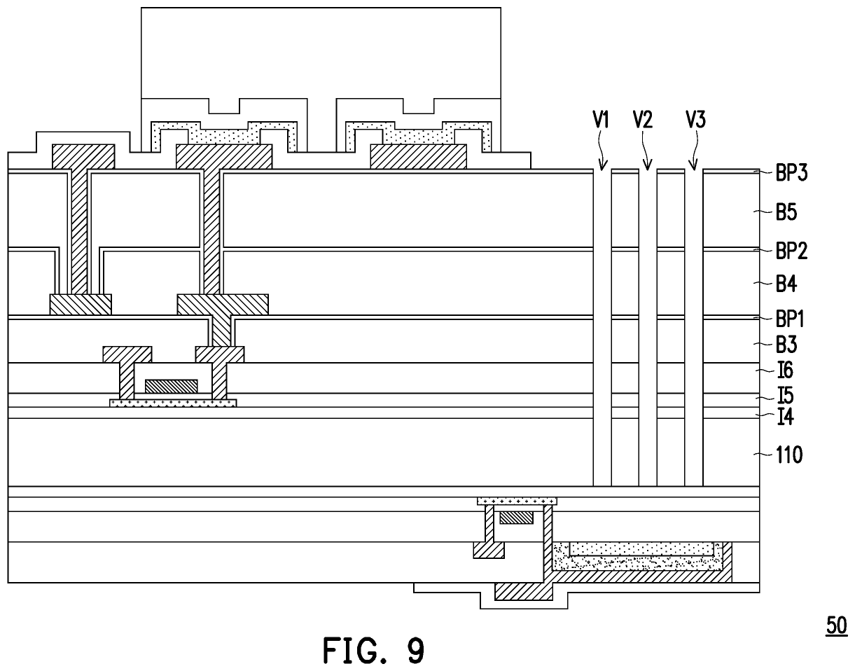

FIG. 9 is a schematic cross-sectional view of a portion of a display device 50 according to an embodiment of the disclosure. Compared with the display device 20 shown in FIG. 5, the display device 50 shown in FIG. 9 is different in that: the through hole V1, the through hole V2, and the through hole V3 penetrate the insulating layer BP3, the insulating layer B5, the insulating layer BP2, the insulating layer B4, the insulating layer BP1, the insulating layer B3, the insulating layer I6, the insulating layer I5, the insulating layer I4, and the substrate 110. Thereby, the display device 50 may achieve an improved light collimation effect.

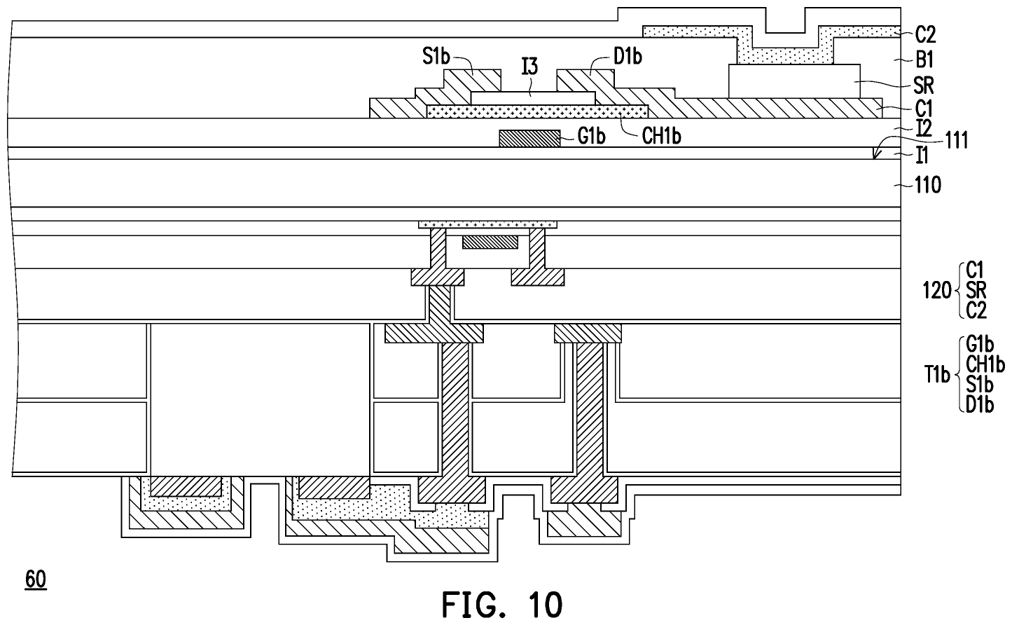

Other embodiments are further explained below with reference to FIG. 10 to FIG. 12, and the reference numbers and relevant contents illustrated in FIG. 1 to FIG. 3 are also applicable in the following embodiments, which should however not be construed as limitations in the disclosure.

FIG. 10 is a schematic cross-sectional view of a portion of a display device 60 according to an embodiment of the disclosure. Compared with the display device 10 shown in FIG. 2, the display device 60 shown in in FIG. 10 is different in that: on the first surface 111 of the substrate 110, the display device 60 may include a first switch element T1b, which is an oxide TFT, and the first switch element T1b is electrically connected to the sensing element 120.

The first switch element T1b is located on the insulating layer I1, for instance. The first switch element T1b includes a gate G1b, a source S1b, a drain D1b, and a semiconductor layer CH1b. The gate G1b is located on the insulating layer I1. The semiconductor layer CH1b overlaps with the gate G1b, and the insulating layer I2 is sandwiched between the semiconductor layer CH1b and the gate G1b. The insulating layer I3 is located on the semiconductor layer CH1b. The source S1b and the drain D1b are separately located on two ends of the insulating layer I3, and the source S1b and the drain D1b are respectively connected to two ends of the semiconductor layer CH1b. The gate G1b may be electrically connected to the driving element 140 via a scan line (not shown) and the transfer wire 150, and the source S1b may be electrically connected to the driving element 140 via a data line (not shown) and the transfer wire 150. In this embodiment, the first switch element T1b includes the oxide semiconductor layer CH1b; that is, the semiconductor layer CH1b includes IGZO. The first switch element T1b is implemented in form of the bottom-gate TFT as an example, which should however not be construed as a limitation in the disclosure. According to other embodiments, the first switch element T1b may also be a top-gate TFT or another suitable TFT.

The insulating layer B1 covers the first switch element T1b. The sensing element 120 is disposed on the insulating layer B1 and electrically connected to the first switch element T1b. The sensing element 120 includes the opposite electrode C1, the transparent electrode C2, and the sensing layer SR.

The opposite electrode C1 is located on the insulating layer I2, and the opposite electrode C1 is electrically connected to the first switch element T1b. For instance, the opposite electrode C1 is electrically connected to the drain D1b. In this embodiment, the opposite electrode C1, the source S1b, and the drain D1b belong to the same film layer. In some embodiments, the opposite electrode C1 and the drain D1b are physically connected to each other. In this embodiment, the opposite electrode C1 is closer to the substrate 110 than the transparent electrode C2. A material of the opposite electrode C1 is, for instance, molybdenum, aluminum, titanium, copper, gold, silver, other conductive materials, or at least two of the above-mentioned materials stacked together.

The sensing layer SR is located on the opposite electrode C1. A material of the sensing layer SR is, for instance, SRO or other suitable materials. In this embodiment, the opposite electrode C1 is located between the sensing layer SR and the substrate 110.

The transparent electrode C2 is located on the sensing layer SR, and the sensing layer SR is located between the transparent electrode C2 and the substrate 110. A material of the transparent electrode C2 is a transparent conductive material, such as ITO, IZO, ATO, AZO, IGZO, other suitable oxides, or a stacked layer containing at least two of the above-mentioned materials. In this embodiment, the display device 60 further includes the passivation layer B2, and the passivation layer B2 may cover the transparent electrode C2.

In this embodiment, the first switch element T1b of the display device 60 is an oxide TFT. Since a dark current (Ioff) of the oxide thin TFT is very low, the display device 60 may have a sufficiently high light current/dark current ratio (Iph/Ioff) and may perform more gray-level slicing operations, whereby the resultant fingerprint image contrast quality is improved. At the same time, an area occupied by the sensing element 120 may also be reduced, so that the resolution of the fingerprint image may be improved.

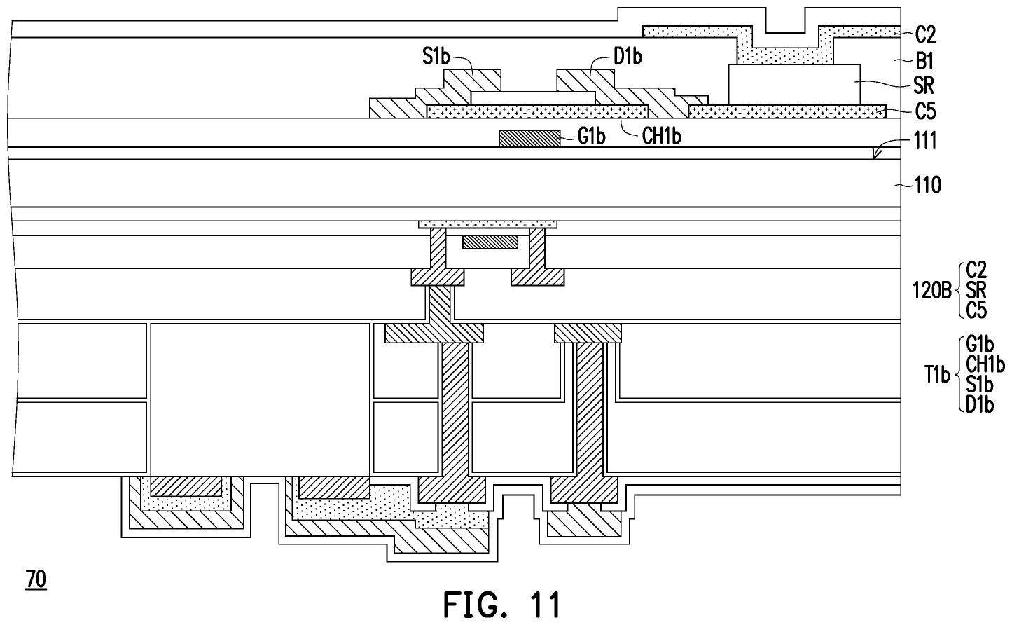

FIG. 11 is a schematic cross-sectional view of a portion of a display device 70 according to an embodiment of the disclosure. Compared with the display device 60 shown in FIG. 10, the display device 70 shown in FIG. 11 is different in that: on the first surface 111 of the substrate 110, the first switch element T1b of the display device 70 may be electrically connected to a sensing element 120B. The first switch element T1b includes the gate G1b, the source S1b, the drain D1b, and the semiconductor layer CH1b, and the semiconductor layer CH1b includes IGZO. The sensing element 120B is disposed in the insulating layer B1 and includes an opposite electrode C5, the transparent electrode C2, and the sensing layer SR, and the opposite electrode C5 and the semiconductor layer CH1b belong to the same film layer, thereby simplifying manufacturing steps of the first switch element T1b and the sensing element 120B.

For instance, in this embodiment, the opposite electrode C5 and the semiconductor layer CH1b are both formed by patterning an IGZO semiconductor layer. Note that when the sensing layer SR is formed on the IGZO semiconductor layer acting as the opposite electrode C5, hydrogen atoms enter the IGZO semiconductor layer in contact with the sensing layer SR, and thus the IGZO semiconductor layer acting as the opposite electrode C5 may become an IGZO conductor layer. That is, the opposite electrode C5 includes the IGZO conductor layer.

In this embodiment, the opposite electrode C5 is electrically connected to the drain D1b. In some embodiments, the opposite electrode C5 and the drain D1b are physically connected to each other. In this embodiment, the opposite electrode C5 is closer to the substrate 110 than the transparent electrode C2. In this embodiment, the opposite electrode C5 is located between the sensing layer SR and the substrate 110.

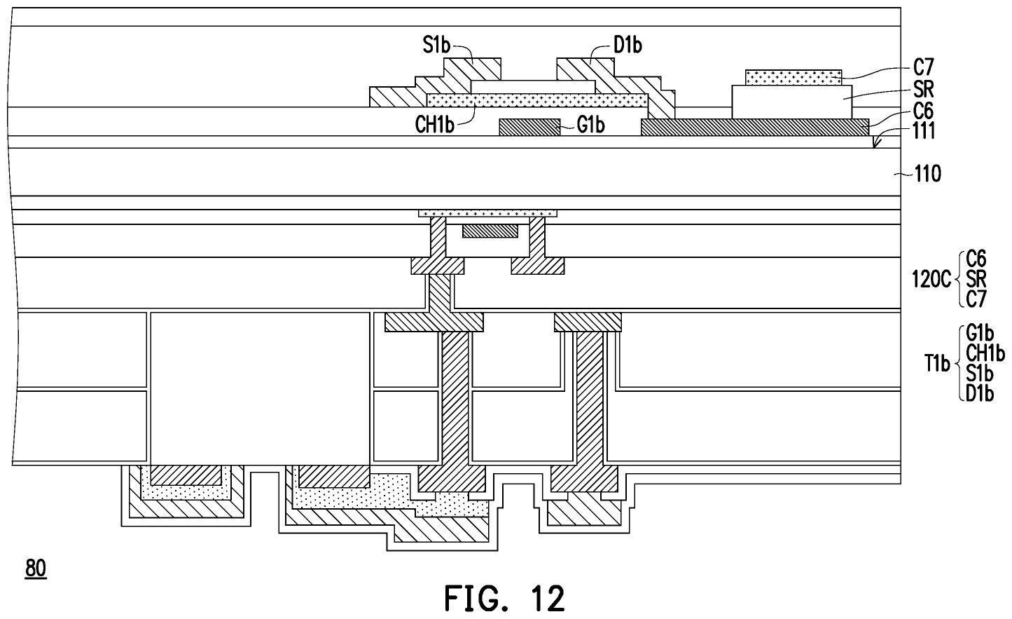

FIG. 12 is a schematic cross-sectional view of a portion of a display device 80 according to an embodiment of the disclosure. Compared with the display device 60 shown in FIG. 10, the display device 80 shown in FIG. 12 is different in that: on the first surface 111 of the substrate 110, the first switch element T1b of the display device 80 may be electrically connected to a sensing element 120C. The first switch element T1b includes the gate G1b, the source S1b, the drain D1b, and the semiconductor layer CH1b, the sensing element 120C includes an opposite electrode C6, a transparent electrode C7, and the sensing layer SR, the opposite electrode C6 and the gate G1b belong to the same film layer, and the transparent electrode C7 and the semiconductor layer CH1b belong to the same film layer.

In this embodiment, a material of the opposite electrode C6 and the gate G1b is, for instance, molybdenum, aluminum, titanium, copper, gold, silver, other conductive materials, or two or more of the above-mentioned materials stacked together. According to this embodiment, in a subsequent baking process, hydrogen atoms enter the IGZO semiconductor layer acting as the transparent electrode C7, and thus the IGZO semiconductor layer acting as the transparent electrode C7 may become the IGZO conductor layer; that is, the transparent electrode C7 includes the IGZO conductor layer. In this embodiment, the opposite electrode C6 and the gate G1b may be formed in the same step, and the transparent electrode C7 and the semiconductor layer CH1b may be formed in the same step; hence, the manufacturing steps of the first switch element T1b and the sensing element 120C may be simplified.

To sum up, in the display device provided in one or more embodiments of the disclosure, the sensing element and the light-emitting element are disposed on different surfaces of the substrate, so that the sensing element does not affect the aperture ratio of the display device nor reduce the aperture ratio of the display device. In addition, the display device of the disclosure can be electrically connected to the element on the opposite to each other surface of the substrate by means of a transfer wire to improve the screen-to-body ratio of the display device. In addition, the display device of the disclosure may also overlap with the orthogonal projection of the first switch element and the second switch element on the substrate. In this way, the projection area of the first switch element and the second switch element on the substrate can be reduced, thereby increasing the aperture ratio.

It will be apparent to those skilled in the art that various modifications and variations can be made to the disclosed embodiments without departing from the scope or spirit of the disclosure. In view of the foregoing, it is intended that the disclosure covers modifications and variations provided they fall within the scope of the following claims and their equivalents.

What is claimed is:

1. A display device, comprising:
a substrate, having a first surface, a second surface, and a side surface, wherein the first surface and the second surface are opposite to each other, and the side surface is connected to the first surface and the second surface;
a sensing element, disposed on the first surface of the substrate;
a light-emitting element, disposed on the second surface of the substrate;
a driving element, disposed on the first surface or the second surface of the substrate; and
a transfer wire, disposed on the side surface of the substrate, wherein the driving element is electrically connected to the light-emitting element or the sensing element via the transfer wire, and an orthogonal projection of the sensing element on the substrate is located outside an orthogonal projection of the light-emitting element on the substrate.

2. The display device according to claim 1, wherein the driving element is disposed on the second surface of the substrate, and the driving element is electrically connected to the sensing element via the transfer wire.

3. The display device according to claim 2, further comprising a cover plate, wherein the sensing element is located between the cover plate and the substrate.

4. The display device according to claim 1, wherein the driving element is disposed on the first surface of the substrate, and the driving element is electrically connected to the light-emitting element via the transfer wire.

5. The display device according to claim 4, further comprising a cover plate, wherein the substrate is located between the cover plate and the sensing element.

6. The display device according to claim 4, further comprising a first switch element disposed on the first surface of the substrate and electrically connected to the sensing element, and an orthogonal projection of the first switch element on the substrate overlaps with the orthogonal projection of the light-emitting element on the substrate.

7. The display device according to claim 6, wherein the sensing element comprises:
an opposite electrode, electrically connected to the first switch element;
a sensing layer, disposed on one side of the opposite electrode; and
a transparent electrode, disposed on one side of the sensing layer, wherein the sensing layer is located between the opposite electrode and the transparent electrode, and an orthogonal projection of the transparent electrode on the substrate overlaps an orthogonal projection of the opposite electrode on the substrate.

8. The display device according to claim 7, wherein the transparent electrode is located between the sensing layer and the substrate.

9. The display device according to claim 4, further comprising at least one through hole, wherein an orthogonal projection of the at least one through hole on the substrate overlaps with the orthogonal projection of the sensing element on the substrate.

10. The display device according to claim 9, wherein the at least one through hole penetrates the substrate.

11. A display device, comprising:
a substrate, having a first surface and a second surface opposite to each other;
a sensing element, disposed on the first surface of the substrate;
a light-emitting element, disposed on the second surface of the substrate; and
a cover plate, disposed on one side of the sensing element, wherein the sensing element is located between the cover plate and the substrate, and an orthogonal projection of the sensing element on the substrate is located outside an orthogonal projection of the light-emitting element on the substrate.

12. The display device according to claim 11, further comprising a first switch element disposed on the first surface of the substrate and electrically connected to the sensing element, wherein an orthogonal projection of the first switch element on the substrate is located outside the orthogonal projection of the light-emitting element on the substrate.

13. The display device according to claim 12, further comprising a second switch element disposed on the second surface of the substrate and electrically connected to the light-emitting element, wherein an orthogonal projection of the second switch element on the substrate is located outside the orthogonal projection of the light-emitting element on the substrate.

14. The display device according to claim 13, wherein the orthogonal projection of the second switch element on the substrate overlaps with the orthogonal projection of the first switch element on the substrate.

15. The display device according to claim 12, wherein the sensing element comprises:
an opposite electrode, electrically connected to the first switch element;
a sensing layer, disposed on one side of the opposite electrode; and
a transparent electrode, disposed on one side of the sensing layer, wherein the sensing layer is located between the opposite electrode and the transparent electrode, and an orthogonal projection of the transparent electrode on the substrate overlaps an orthogonal projection of the opposite electrode on the substrate.

16. The display device according to claim 15, wherein the sensing layer is located between the transparent electrode and the substrate.

17. The display device according to claim 15, wherein the first switch element comprises a source and a drain, and the opposite electrode, the source, and the drain belong to a same film layer.

18. The display device according to claim 15, wherein the first switch element comprises a semiconductor layer, and the opposite electrode and the semiconductor layer belong to a same film layer.

19. The display device according to claim 18, wherein the semiconductor layer comprises indium gallium zinc oxide.

20. The display device according to claim 15, wherein the first switch element comprises a gate, and the opposite electrode and the gate belong to a same film layer.
